(19) United States
(12) Patent Application Publication
(10) Pub. No.: US 2002/0004268 A1
(43) Pub. Date: Jan. 10, 2002

(54) METHOD OF POLISHING POLYSILICON

(76) Inventors: TONY LIN, KAOHSIUNG HSIEN (TW); JIH-WEN CHOU, HSINCHU (TW); C.C. HSUE, HSINCHU (TW)

Correspondence Address: J C Venture Inc, 4 Venture, Suite 250, Irvine, CA, 92618, US

(21) Appl. No.: 09/246,648

(22) Filed: Feb. 8, 1999

(51) Int. Cl. H01L 21/8238; H01L 23/58

(52) U.S. Cl. 438/221

(57) ABSTRACT

A method of polishing a polysilicon layer by using a chemical mechanical polishing process is described. A semiconductor substrate is provided, and a shallow trench isolation structure is formed on the semiconductor substrate such that the substrate has an uneven surface. A first polysilicon layer is formed on the semiconductor substrate and the shallow trench isolation structure. A polishing step is performed on the first polysilicon layer to planarize the first polysilicon layer. A second polysilicon layer is formed on the first polysilicon layer, wherein an interface is formed between the second polysilicon layer and the first polysilicon layer.

### BACKGROUND OF THE INVENTION

1. Field of Invention

The present invention generally relates to semiconductor fabrication, and more particularly to a method of polishing a polysilicon layer by using a chemical mechanical polishing (CMP) process.

2. Description of Related Art

In the semiconductor process there are many insulating structures such as field oxide or shallow trench isolation (STI) for insulating semiconductor devices in active regions on a substrate. In accordance with advances in semiconductor process techniques, the level of integration of integrated circuits increases so that the size of MOS device must be minimized to fulfill the requirements of semiconductor fabrication. The STI structure is better than the field oxide for use in the sub-0.25 μm semiconductor process. STI is an important factor that allows high speed and high-packing-density CMOS-LSIs to be realized. After forming the STI structure, a polysilicon layer is usually then formed on the STI structure. Then MOS devices are then formed on the polysilicon layer.

However, certain problems arise in the conventional polysilicon layer formed on the STI structure. The polysilicon layer formed on the STI structure has uneven topography because the protruding STI structure imparts an overall uneven surface to the substrate. The thickness and uniformity of STI structure after polishing is very critical to polysilicon critical dimension control. If the remaining oxide of the STI structure protrudes too severely from the substrate, the standard deviation of the critical dimension control increases linearly in proportion to the thickness of the remaining oxide. A misalignment of the exposure step in the photolithography process is more serious and the critical dimension control is more difficult in sub-0.25 μm semiconductor process.

In addition, there are usually ions such as boron ions doped in the polysilicon layer.

There are also many grain boundaries formed in the polysilicon layer. The ions accordingly penetrate or diffuse along the grain boundaries to the substrate or STI structure to result in ion penetration such as Boron penetration. As MOS devices are scales down, boron penetration (or penetration by other ions) even more seriously decreases the reliability of MOS devices.

### SUMMARY OF THE INVENTION

Accordingly, the object of the present invention is to provide a method of polishing a polysilicon layer formed on a STI structure that uses a chemical mechanical polishing process.

Another object of the present invention is to provide a method of polishing a polysilicon layer formed on a STI structure such that the polysilicon layer has a planar surface. The planar polysilicon layer increases the ability to control the polysilicon critical dimension and reduce the misalignment problem of the following photolithography process.

Still another object of the present invention is to provide a method of polishing a polysilicon layer formed on the STI structure in which there is an interface in the polysilicon layer that changes the grain boundaries to stop or change the path of ion penetration in the polysilicon layer.

To achieve these and other advantages and in accordance with the purpose of the invention, as embodied and broadly described herein, the invention provides a method of polishing a polysilicon layer formed on the STI structure by using a chemical mechanical polishing process. A semiconductor substrate is provided, wherein an insulating plug such as a STI structure is formed on the semiconductor substrate. A first conductive layer is formed on the semiconductor substrate and the STI structure by chemical vapor deposition (CVD). The material of the first conductive layer includes doped polysilicon. A polishing step such as chemical mechanical polishing is performed on the first conductive layer to planarize the first conductive layer. A second conductive layer is formed on the first conductive layer by using chemical vapor deposition, wherein an interface is formed between the second conductive layer and the first conductive layer. The material of the second conductive layer includes doped polysilicon.

To achieve these and other advantages and in accordance with the purpose of the invention, as embodied and broadly described herein, the invention provides a structure of a polysilicon layer. A semiconductor substrate is provided. An insulating plug such as a STI structure is located in the semiconductor substrate and imparts an overall uneven surface to the substrate. A first conductive layer is located on the semiconductor substrate and the insulating plug. The material of the first conductive layer includes doped polysilicon. The surface of the first conductive layer is planarized by a chemical mechanical polishing process. A second conductive layer is located on the first conductive layer. The material of the second conductive layer includes doped polysilicon. An interface is located between the second conductive layer and the first conductive layer.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1 through 6 are schematic, sequential cross-sectional diagrams showing a method of polishing a polysilicon layer formed on a STI structure by using a chemical mechanical polishing process.

### DESCRIPTION OF THE PREFERRED EMBODIMENTS

The invention provides a method of polishing a polysilicon layer formed on STI structure that uses a chemical mechanical polishing process. After forming STI structure, a first polysilicon layer is formed on the STI structure. A planarization step such as chemical mechanical polishing process is performed on the first polysilicon layer. Then a second polysilicon layer is formed on the first polysilicon layer. An interface is accordingly located between the second polysilicon layer and the first polysilicon layer for changing the path of ion penetration in the polysilicon layer to improve the ability of controlling the polysilicon critical dimension.

The above planarization step is particularly important for the high density photolithography process. The planarization process is used to form a planar surface. The planar surface effectively reduces the scattering that occurs during exposure in the photolithography process to perform pattern transfer. Conventional planarization processes include spin-on glass or chemical mechanical polishing. When semiconductor fabrication techniques are scaled down to the sub-half-micron level, the spin-on glass process is no longer used. The chemical mechanical polishing process is currently only method of providing global planarization for very-large scale integration (VLSI) or ultra-large scale integration (ULSI). The chemical mechanical polishing process includes mechanical polishing process that combines a chemical reagent and abrasives to polish the uneven topography of the wafer. The invention uses chemical mechanical polishing to polish a polysilicon layer formed on the STI structure as a way of improving the ability to control the critical dimension of the polysilicon.

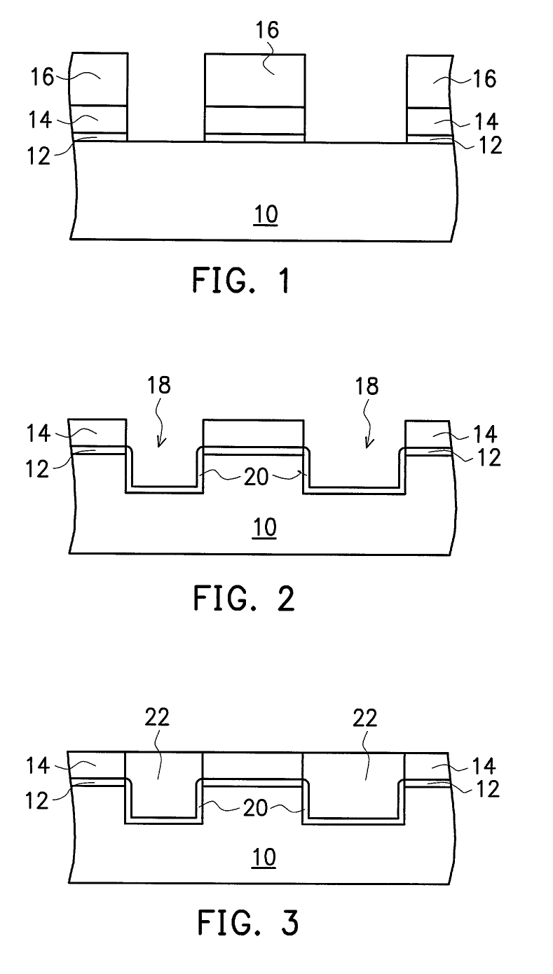

FIGS. 1 through 6 are schematic, sequential cross-sectional diagrams showing a method of polishing a polysilicon layer formed on a STI structure that uses a chemical mechanical polishing process. As shown in FIG. 1, a semiconductor substrate 10 is provided. A pad oxide layer 12 and a silicon nitride layer 14 are formed on the semiconductor substrate 10. Then a photolithography process is performed. That is, a photoresist layer 16 is formed and patterned on the silicon nitride layer 14. The silicon nitride layer 14 and the pad oxide layer 12 are etched to expose the semiconductor substrate 10 by using the photoresist layer 16 as a mask. The method of etching the silicon nitride layer 14 and the pad oxide layer 12 is preferably anisotropic dry etching.

As shown in FIG. 2, the photoresist layer 16 is removed. A trench 18 is formed in the semiconductor substrate 10 by etching. The method of forming the trench 18 is preferably anisotropic dry etching using the silicon nitride layer 14 as a mask. A thermal oxidation is performed to form a thin liner oxide layer 20 in the trench 18.

The liner oxide layer 20 is located on the bottom and sidewalls of the trench 18 but does not fill the trench 18.

As shown in FIG. 3, an insulating layer 22 is formed to fill the trench 18. The method of forming the insulating layer 22 includes chemical vapor deposition. The material of the insulating layer 22 includes silicon oxide. A polishing process is then performed on the insulating layer 22 to expose the surface of the silicon nitride layer 14. The surface of the silicon nitride layer 14 and the surface of the insulating layer 22 are about equally high.

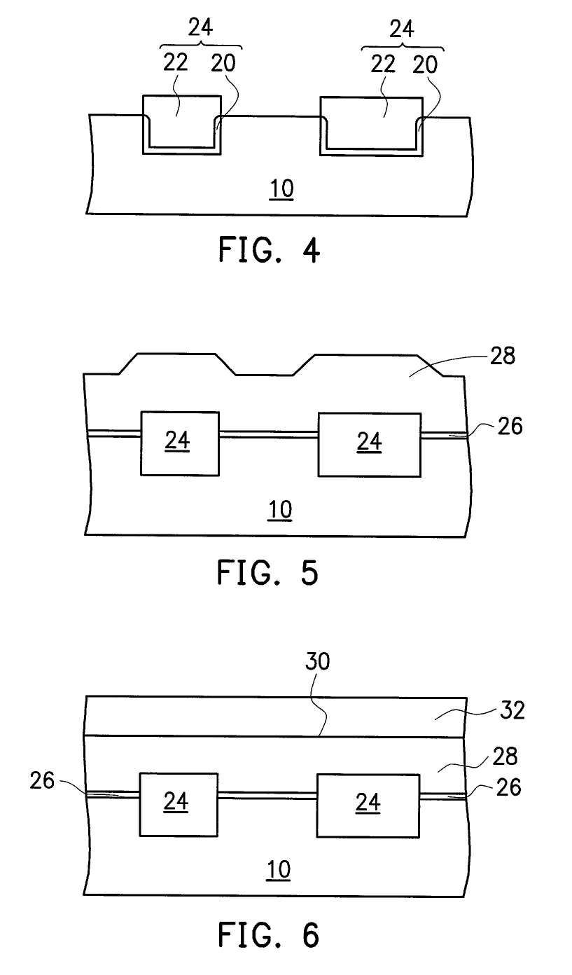

As shown in FIG. 4, the silicon nitride layer 14 is removed by using hot phosphoric acid solution. The liner oxide layer 20 and the insulating layer 22 remain in the trench 18 and on the semiconductor substrate 10 to form an insulating plug 24. The insulating plug 24 is used as STI structure. The surface of the insulating plug 24 and the surface of the semiconductor substrate 10 are not equally high.

As shown in FIG. 5, a gate oxide layer 26 is formed on the semiconductor substrate 10. The method of forming the gate oxide layer 26 is preferably thermal oxidation.

A first conductive layer 28 is then formed on the gate oxide layer 26 and the insulating plug 24. The method of forming the first conductive layer 28 is preferably chemical vapor deposition. The material of the first conductive layer 28 is preferably doped polysilicon. The first conductive layer 28 has an uneven topography.

As shown in FIG. 6, a polishing process is performed on the first conductive layer 28 to planarize the uneven topography. The uneven surface of the first conductive layer 28 is accordingly eliminated to form a planar surface 30. A second conductive layer 32 is formed on the first conductive layer 28. The method of forming the second conductive layer 32 is preferably chemical vapor deposition. The material of the second conductive layer 32 is preferably doped polysilicon. The planar surface 30 acts as an interface 30 between the first conductive layer 28 and the second conductive layer 32. The polysilicon layer of the invention is accordingly planar to improve the ability of controlling the polysilicon critical dimension. Furthermore, the interface 30 of the invention is formed in the polysilicon layer for changing the grain boundaries, which in turn stop or change the path of ion penetration in the polysilicon layer. Penetration by boron and other ions thus decreases, which improves the reliability and performance of MOS devices.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of polishing a polysilicon layer, comprising:
providing a semiconductor substrate, wherein an insulating plug is formed on the semiconductor substrate, and the surfaces of the insulating plug and the semiconductor substrate are not equally high;
forming a first conductive layer on the semiconductor substrate and the insulating plug;
performing a polishing step on the first conductive layer to planarize the first conductive layer; and
forming a second conductive layer on the first conductive layer, wherein an interface is located between the second conductive layer and the first conductive layer.

2. The method of polishing a polysilicon layer of claim 1, wherein the insulating plug includes a field oxide layer.

3. The method of polishing a polysilicon layer of claim 1, wherein the insulating plug includes a shallow trench isolation structure.

4. The method of polishing a polysilicon layer of claim 1, wherein the polishing step includes chemical mechanical polishing.

5. The method of polishing a polysilicon layer of claim 1, wherein the material of the insulating plug includes silicon oxide.

6. The method of polishing a polysilicon layer of claim 1, wherein the method of forming the first conductive layer includes chemical vapor deposition.

7. The method of polishing a polysilicon layer of claim 1, wherein the material of the first conductive layer includes doped polysilicon.

8. The method of polishing a polysilicon layer of claim 1, wherein the method of forming the second conductive layer includes chemical vapor deposition.

9. The method of polishing a polysilicon layer of claim 1, wherein the material of the first conductive layer includes doped polysilicon.

10. A structure of a polysilicon layer, comprising:
a semiconductor substrate, wherein an insulating plug is located in the semiconductor substrate such that the substrate has an uneven surface because the surfaces of the insulating plug and the semiconductor substrate are not equally high;
a first conductive layer located on the semiconductor substrate and the insulating plug, wherein the first conductive layer has a planar surface;
a second conductive layer located on the first conductive layer; and
an interface located between the second conductive layer and the first conductive layer.

11. The structure of a polysilicon layer of claim 10, wherein the insulating plug includes a field oxide layer.

12. The structure of a polysilicon layer of claim 10, wherein the insulating plug includes a shallow trench isolation structure.

13. The structure of a polysilicon layer of claim 1O, wherein the interface is formed by chemical mechanical polishing.

14. The structure of a polysilicon layer of claim 10, wherein the material of the insulating plug includes silicon oxide.

15. The structure of a polysilicon layer of claim 10, wherein the method of forming the first conductive layer includes chemical vapor deposition.

16. The structure of a polysilicon layer of claim 10, wherein the material of the first conductive layer includes doped polysilicon.

17. The structure of a polysilicon layer of claim 10, wherein the method of forming the second conductive layer includes chemical vapor deposition.

18. The structure of a polysilicon layer of claim 10, wherein the material of the second conductive layer includes doped polysilicon.
